(19) United States
(12) Patent Application Publication
(10) Pub. No.: US 2024/0339387 A1
(43) Pub. Date: Oct. 10, 2024

(54) SEMICONDUCTOR POWER MODULE

(71) Applicant: Danfoss Silicon Power GmbH, Flensburg (DE)

(72) Inventors: Jacek RUDZKI, Kiel (DE); Mohammadhadi MAGHSOUDI, Nordborg (DK); Lars PAULSEN, Hollingstedt (DE); Tino FILIPIAK-RESSEL, Kiel (DE); Holger BEER, Langballig (DE); Tobias SCHUETZ, Flensburg (DE)

(21) Appl. No.: 18/625,482

(22) Filed: Apr. 3, 2024

(30) Foreign Application Priority Data
Apr. 4, 2023 (DE) 102023108539.5

(51) Int. Cl. H01L 23/498; H01L 21/48; H01L 21/56; H01L 23/10; H01L 23/31

(52) U.S. Cl. CPC H01L 23/49811; H01L 21/4853; H01L 21/565; H01L 23/10; H01L 23/3121; H01L 23/49838

(57) ABSTRACT

A semiconductor power module includes one or more semiconductors placed on a substrate. At least one contact pin extends basically perpendicular to the substrate and is electrically connected to the substrate or the semiconductor via a pin foot. A terminal end of the contact pin protrudes outside an encapsulation compound encapsulating at least partially the substrate, the one or more semiconductors, and the contact pin. At least one sealing ring and at least one washer are received by a pin shaft of the contact pin such that they rest on the pin foot. The washer is fixed by the encapsulation compound, and the sealing ring is held in longitudinal direction of the pin shaft in an elastically deformed state by the washer.

### CROSS-REFERENCE RELATED TO APPLICATION

This application claims foreign priority benefits under 35 U.S.C. § 119 from German Patent Application No. 102023108539.5, filed Apr. 4, 2023, the content of which is hereby incorporated by reference in its entirety.

### TECHNICAL FIELD

The present invention relates to a semiconductor power module and a method for manufacturing such a semiconductor power module.

### BACKGROUND

In the field of power electronics, framed power modules and molded power modules are well-known. Such power modules comprise semiconductor components such as semiconductor diodes, transistors, thyristors, rectifier, and switches in the form of, for example, IGBTs or MOSFETs. Such components may use silicon-based semiconductors or, as it is becoming more widespread, wide-bandgap semiconductors such as silicon carbide (Sic) or gallium nitride (Gan) based semiconductors. In power modules, it is known to use load and control pins that extend out of the molded housing through an opening provided in a molded housing.

For power modules that use high switching frequencies in operation, particularly where wide-bandgap semiconductor technologies are used, it is essential that the contact pins extend along the shortest possible path while connecting the components and the control electronics or load. Molded power modules having top contacts pins are, however, rare because the required production steps are difficult to carry out.

It is known to have contact pins of the same height as the molding compound, wherein the contact pins are fastened to a substrate before the molding. It is also known to have contact pins that are higher than the molding compound, and therefore extend outside the mold compound in the completed module. These contact pins, too, are fastened to the substrate before the molding process. In order to carry out the molding process, it is required to apply sealing elements which are firmly or semi-firmly connected to the contact pins. These sealing elements need to be fixed onto the contact pins before the contact pins are attached to the substrate in order to fulfil its sealing function properly.

One of the disadvantages of the prior art solutions is that the sealing elements have to be connected to the contact pins before the contact pins are attached to the substrate. Accordingly, ultrasonic welding of contact pins is difficult and requires complex tools. Therefore, methods for attaching contact pins to substrates, such as for example soldering or adhesive bonding are seldomly used, as they are complex and expensive. If the mounting of the sealing elements is performed after the attachment of the contact pins (while using the prior art solutions), the sealing elements will not exert any pressure towards the pin shaft and the sealing contour of the opening in the upper mold. This has the undesired consequence that the molding compound can enter the opening in the upper mold tool and cause overflow of the molding compound during the molding process and therewith contamination of the mold and/or the contacting terminal of the contact pin.

Thus, there is a need for a semiconductor power module, which does not show the above mentioned disadvantages of the prior art.

### SUMMARY

It is thus an object of the present invention to provide a method for an improved manufacturing of semiconductor power modules, in which a sufficiently tight sealing of the opening in the upper mold tool can be established in order to prevent an overflow of molding compound and/or contamination of the contacting terminal of the contact pin. The improved manufacturing method should provide a simple, robust, and cost effective manufacturing process of semiconductor power modules with a high reproducibility. It is also an object to provide a semiconductor power module that can be manufactured without the occurrence of the above-mentioned disadvantages.

The object of the present invention is achieved by a semiconductor power module as defined in independent claim 1, and by a method as defined in the parallel independent claim 12. Preferred embodiments are defined in the dependent subclaims, explained in the following description, and illustrated in the accompanying drawings.

The semiconductor power module according to the invention comprises one or more semiconductors placed on a substrate. At least one contact pin extends in general perpendicular to the substrate and electrically connects the substrate via a pin foot, wherein a terminal end of the contact pin protrudes outside a mold compound, encapsulating at least partially the one or more semiconductors, the substrate, and the contact pin. At least one sealing ring and at least one washer are received by a pin shaft of the contact pin such that they can rest on the pin foot. Thereby the washer is being fixed by the mold compound, such that the sealing ring is being held deformed elastically in longitudinal direction of the shaft and being fixed against the foot by the washer.

The substrate of the power module according to the invention, on which the one or more semiconductors are placed, may be a Direct Copper Bonding (DCB) substrate, like a Sic-, AlN-ceramic or like. It may be advantageous to use a DCB ceramic due to its good thermal conductivity. As known in the art on such a semiconductor DCB ceramic, different kind of semiconductor devices like semiconductor diodes, transistors, thyristors, or switches can be attached.

According to the invention the DCB substrate as well as the semiconductor devices can be electrically contacted on the outside of the power module laterally, i.e. basically parallel to the substrate main extensions, by means of electrical contact pins or terminals. According to the invention, at least one further electrical contact pin extends basically perpendicular, i.e. rectangular or with an angle close to 90° to the substrate, and projects outside the power module with a terminal on a side parallel to the substrate. The perpendicular contact pin is electrically connected to the substrate or to at least one semiconductor arranged on the substrate. In the further course of the description of the invention any orientation or form of a contacting pin is covered by the expression perpendicular contact pin as long as a terminal portion of the contact pin projects outside of the power module on the top or bottom side of the power module, even though the contact pin shows an S-form or the like.

The perpendicular pin may be fixed to the substrate via its pin foot by soldering, ultrasonic welding, laser welding, bonding, or sintering. In one embodiment, the pin is a press-fit pin adapted for the insertion into holes in the substrate, e.g. a printed circuit board (PCB), a further example for a DCB substrate according to the invention. In one embodiment, the contact pin may comprise holes or threaded holes formed in the pin foot to be connected to the substrate by using a screw connection to electrically connect and fix the pin on the substrate.

Preferably after fixing the perpendicular contact to the substrate or to the semiconductor a sealing ring and a washer is placed on the pin shaft of the contact pin such that the sealing ring is elastically deformed when the molding form for encapsulating at least partially the one or more semiconductors, the substrate, and the contact pin is closed. Commonly a molding form is built by two mold halves, wherein the substrate, the one or more semiconductors, and the contact pin are placed first in the first (lower) mold half. In this state the perpendicular contact pin projects over the mold partition plane with its terminal end. The arrangement of the sealing ring and the washer also protrudes over the partition plane such that the sealing ring is elastically deformed when the second mold half is placed on the first mold half in order to close the cavity in a sealed manner at the partition plane. In this state the remaining cavity of the encapsulating mold is prepared for being filled with encapsulation compound to enclose and encapsulate at least partially the substrate, the one or more semiconductors, and the contact pin.

In the area of the terminal end of the contact pin, a recess or opening is formed in the upper mold half into which only the terminal end of the contact pin can protrude without being forced or bend, and in order to not cause any damage and/or mechanical stress to the semiconductor or the substrate. The recess or opening cross section is dimensioned smaller than a diameter/radial extension of the washer such that the area of second mold adjacent to the recess/opening is pressed against the washer and a pressing force is forwarded by the washer to deform the sealing ring elastically in pin shaft direction when the upper mold half is placed on the partition plane of lower mold half in order to close the cavity. In this closed state of the mold, molding compound/material can be filled into the cavity of the mold while, according to the invention, the sealing ring remains deformed. Due to the elastically axial deformation of the sealing ring, restoring forces of the sealing ring provide a good sealing force in axial direction, with which the washer is pressed towards the inner surface of the upper mold half and the sealing ring seals with lower surface of the washer and at the lower side seals with the pin foot, or with a second washer in case the pin foot does not provide with a suitable sealing surface. These elastic restoring forces of the sealing ring have to be maintained at least until the molding material/encapsulation compound is cured. Once the molding material is cured, the washer is encapsulated by the molding/encapsulation material and securely held in place. In the current state the cured molding material is solid, and cannot flow anymore, hence cannot contaminate the terminal end.

According to the invention, the sealing ring is also fixed at the radial outside by the molding material during encapsulation of the one or more semiconductors, the substrate, and the contact pin. Once the molding component is cured, the washer and sealing ring are not able to move or to expand in pin shaft direction. Hence, the sealing ring is maintained in its elastically deformed state when the molding material is cured/hardened.

In one embodiment, according to the invention, the elastically, in pin shaft direction deformed/compressed sealing ring seals with the washer and at its inner side with the pin shaft too, such that no molding material can run along the pin shaft and enter the recess/opening in the second mold half while filling the mold. Thus, no molding material can contaminate the terminal end of the perpendicular contact pin. In the compressed/deformed state the sealing ring is flattened in its axial direction while expanding in the radial direction. Even though in this embodiment, the sealing ring also seals with the pin shaft due to the radial expansion of the sealing ring, this feature is not essential for the invention, as the sealing contact of the sealing ring in axial direction at the upper side as well as at the lower side already suffice to prevent entry of molding material into the recess in the upper mold half during filling of the cavity. The general O-ring sealing concept with two adjacent flat surfaces is well known by a person skilled in the art, however never used in the encapsulating step for manufacturing power modules.

As the sealing ring is deformed elastically and seals against the pin foot, against the washer or against two washers in case of a sandwiched accommodation, and as the upper washer is forced downwards in pin shaft direction by closing the second mold half, all radial paths for molding material to enter towards the pin shaft are closed in a sealed manner such that no molding material can reach the pin shaft and climb up the pin shaft to contaminate the terminal end.

In a preferred embodiment the sealing ring contacts and rests on the pin foot so that only one washer is necessary which rests on top of the sealing ring such that by closing the mold the washer is pushed down and deforms the sealing ring elastically against the pin foot. In case the pin foot cross section is smaller than the radial extension of the necessary support diameter of the sealing ring or even smaller than the opening in the sealing ring, the sealing ring would rest on the substrate or the semiconductor or any other component of the power module. Even though this is not a preferred embodiment it is covered by the inventive idea as this solution might be feasible as long the substrate or the other components of the power module are not harmed by the force deforming the sealing ring elastically, and as long as no short circuit, creepage, impedance or any other parasitic current caused by the direct contact of the sealing ring with the adjacent components, occurs.

A person skilled in the relevant art realizes that according to the invention the sealing ring and the washer can be mounted on the contact pin also the other way round, i.e. in such a way that the washer contacts the pin foot, and the sealing ring contacts the lower inner surface of the upper mold half. In this embodiment the upper mold half directly deforms the sealing ring elastically when the mold is closed. In this case the sealing ring would be visible on the top of the finished power module. However, in this state the encapsulating material is hardened and no contamination of the terminal end by the encapsulating material can occur, so that a power module according to the invention is obtained likewise.

In a further preferred embodiment of the invention, the sealing ring is sandwiched between two washers in order to be securely held in a deformed state in the closed mold and further in the power module, thereby sealing with both washers and potentially with the pin shaft. This embodiment is preferred in case the pin foot shows a too small radial extension or a support surface not suitable for sealing directly with the sealing ring, i.e. when the supporting surface of the pin foot is too small to assure a reliable elastic deformation of the sealing ring without damaging the sealing ring or the components of the power module arranged on the substrate or damaging the bonded/printed circuit. In case there is a risk that the sealing ring or the washer contacts the bonded circuit on the substrate, it is preferred that the lower washer contacting the circuit and/or the pin foot is made of an electrically non-conductive material in order to prevent short circuit, creepage, impedance, inductance, or any other parasitic current.

The sealing ring is made preferably of a natural or synthetic elastomeric or silicone material which can be deformed elastically such that, due to internal restoring forces, the sealing ring is capable to maintain a sealing contact against the washer and/or the second mold half at least during the molding/encapsulating step with which at least partially the substrate, the one or more semiconductors, and the contact pin are encapsulated. Further, as the sealing ring according to the invention does not have to fulfill any further function than sealing with the washer/washers, the pin foot, and/or the lower surface of the upper mold, the sealing ring is preferably a standard part, i.e. a standardized part which can be purchased easily and cost effective. As the washer or the washers used in accordance with the invention do not have to provide another function than providing axial surfaces apt to seal under pressure with another flat surface or with the sealing ring, the washer/washers can be chosen as purchasable standardized parts too. Standardized washers exist in an enormous variety of diameters and thicknesses. Thicker washers are also called spacer washers or simply spacers. Hence all these variations of washers may be used according to the invention to bridge together with the deformed sealing ring the distance between the pin foot or the substrate and upper outside of the power module housing. In other words, the washer or washers should be select in height such that a length of the package of the sealing ring with one or two washers when mounted on the pin shaft is greater by that amount the sealing ring is deformed elastically when the two mold halves are joined together. Thereby the elastic deformation of the sealing ring should be sufficiently high that the restoring forces of the deformed sealing ring are high enough to ensure a good sealing pressure being high enough to prevent that liquid molding material to enter radially between the pin foot and the sealing ring or the washer, or to enter between the sealing ring and the washer, or between the washer and lower inner surface of the upper mold half.

Further, according to the invention, the at least one washer or both washers are made of metal, plastic, reinforced plastic, or elastic material, depending on economical or technical reasons/requirements in order to avoid short circuit, creepage, inductance or any other parasitic current.

According to the invention the cross section of the contact pin projecting perpendicular or basically perpendicular to the substrate can be of any form, preferably round, oval, or rectangular. Corresponding to the pin shaft cross section the sealing ring or the opening in the sealing ring shows an appropriate form to surround the pin shaft. Not necessarily the washer or the washers have to show the same external or internal form as the sealing ring, as the sealing ring mainly seals with the washer/s in axial direction, i.e. in direction of the pin shaft axis.

In a further embodiment covered by the invention more, than one top contact or bottom contact can be guided to the outside of the housing of a power module by means of a contact pin perpendicular to the substrate connected to an electric element of the power module. In all these cases each pin shaft can be guided outside in the inventive manner separately, i.e. on each pin shaft a sealing ring and at least one washer can be arranged in order that no liquid encapsulating compound could run/flow along the pin shaft and contaminate the terminal end of the contact pin during the encapsulation step of the power module.

In case a power module is designed to have a bottom contact in parallel to a top contact, the inventive idea is applicable in analogous way with the difference that the substrate will be pushed in its final vertical molding position in the first mold half when the second mold half is placed on the partition plane. In this embodiment the lower (first) mold half has to show a similar recess/opening on the bottom side to the recess in the upper mold half in order to accommodate the terminal end of bottom contact pin without stress.

In a further embodiment of the power module according to the invention more than one perpendicular contact pin arranged at one side on the substrate can be sealed in the inventive manner such that their terminal ends are not contaminated by the molding material. Here, each contact pin can receive a sealing ring separately and at least one washer or one probably oval sealing ring and at least one washer may surround all pin shafts. This works in particular when two or more contact pins are of the same electric potential and can reduce the number of parts necessary to assemble the power module. Here, a person skilled in the relevant art will probably use a solution in which the (probably oval or rectangular) sealing ring is sandwiched between two (probably oval or rectangular) washers. A person skilled in the relevant art will also find other possibilities to reduce the number of parts to complete power modules according to the invention having more than one top or bottom contact. Hence all these solutions will be covered by the inventive idea.

With the help of the enclosed Figures preferred embodiments of a power module according to the invention are explained in more detail in order to enhance the understanding of the basic idea of the invention. The present embodiments do not limit the scope of the idea of the invention, but only represent possible design alternatives, to which within the knowledge of a person with skills in the relevant art modifications can be made without leaving the scope of the invention. Therefore, all those modifications and changes are covered by the claimed invention.

### BRIEF DESCRIPTION OF THE DRAWINGS

In the Figures it is shown in:

FIG. 1 a first embodiment of the power module according to the invention before closing the encapsulation mold;

FIG. 2 the power module of FIG. 1 with the encapsulation mold closed;

FIG. 3 the power module of FIG. 1 after removing from the encapsulation mold;

FIG. 4 a second embodiment of the power module according to the invention;

FIG. 5 a third embodiment of the power module according to the invention;

FIG. 6 a fourth embodiment of the power module according to the invention;

FIG. 7 a fifth embodiment of the power module according to the invention; and

FIGS. 8a and 8b two possible embodiments for the contact pin.

### DETAILED DESCRIPTION

For a better traceability and for sake of improving the legibility of the detailed description same reference numbers are used throughout the Figures for indicating equal parts or elements having the same function.

Even though indications are given for the upper and lower directions and locations, they refer only to the orientation of the elements as shown in the Figures and must not coincide with the orientations and locations in the normal usage of a power module according to the invention. So, e.g., a top contact shown in the Figures might be oriented to the bottom or sidewards in the normal usage of the power module according to the invention. The indications concerning the top or the bottom are used merely to enhance the understanding and legibility of the Figures and their description and are derived from the usual positioning of the encapsulation mold and the used mold halves.

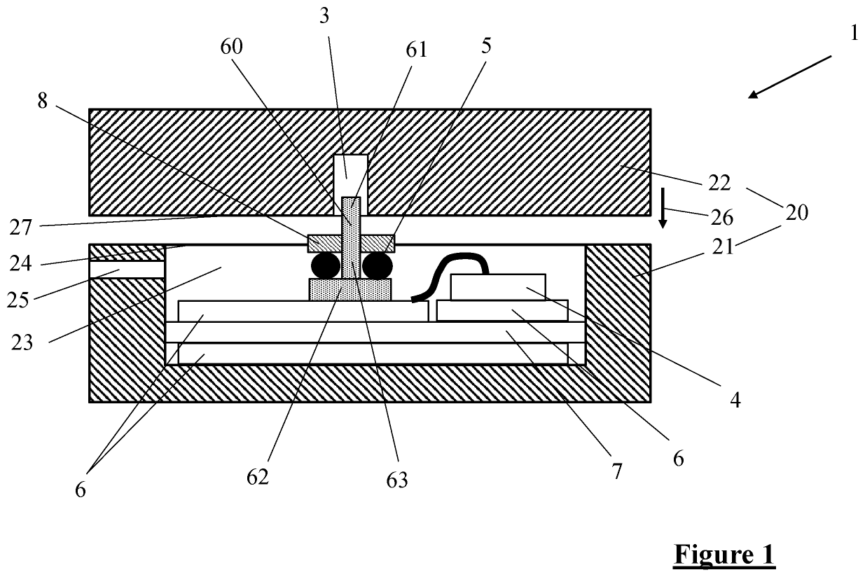

FIG. 1 shows a first embodiment of a non-encapsulated power module 1 according to the invention placed in an open encapsulation mold 20, i.e. the situation right before closing the encapsulation mold 20 to perform the encapsulation step with which at least partially a substrate 7 with a bonded or printed circuit 6 applied thereon, one or more semiconductors 4 connected to the bonded/printed circuit 6, and a contact pin 60 protruding basically perpendicular to the substrate 7 are encapsulated with molding compound; also called encapsulation compound or molding material. The perpendicular contact pin 60 is fixed via a pin foot 62, e.g., on the circuit 6 by any known fixing process, like soldering, ultrasonic welding, laser welding, bonding, sintering or by press-fit. It is also covered by the invention that the contact pin 60 is located and fixed with its pin foot 62 to any other component arranged in the power module 1, e.g. a contact pin 60 bonded to the semiconductor 4 via its pin foot 62.

Further to the invention and the exemplary embodiment shown with FIG. 1, after a contact pin 60 is fixed to the substrate, the bonded or printed circuit 6 or to the semiconductor 4, a washer 8 and a sealing ring 5 are received by the pin shaft 63 of the contact pin 60 in that way that the sealing ring 5 contacts the pin foot 62. This (pre-) assembly group consisting of substrate 7 with the bonded or printed circuit 6, the semiconductor 4 and the contact pin 60 with the washer 8 and the sealing ring 5, is placed in a first, lower mold half 21 such that the pin shaft 63 with its terminal end 61 is oriented upright.

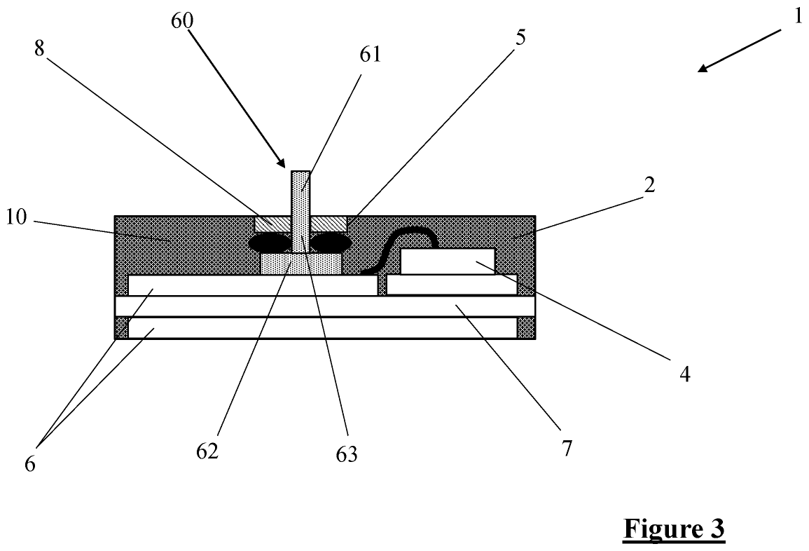

As can be seen in FIG. 1, the first, lower mold half 21 comprises at the upper end a mold parting plane 24 at which the first, lower mold half and the second, upper mold half 22 can be joined together in order to tightly close a cavity 23 of the mold 20. When the mold 20 is closed encapsulation or molding material 10 (see FIG. 3) can be filled in the cavity 23 via a mold inlet 25. After curing of the encapsulation material 10 the finished power module 1 can be removed from the lower mold half 21 after the second, upper mold half 22 is taken away. FIG. 3 shows the power module according to FIGS. 1 & 2 after removing from the encapsulation mold 20.

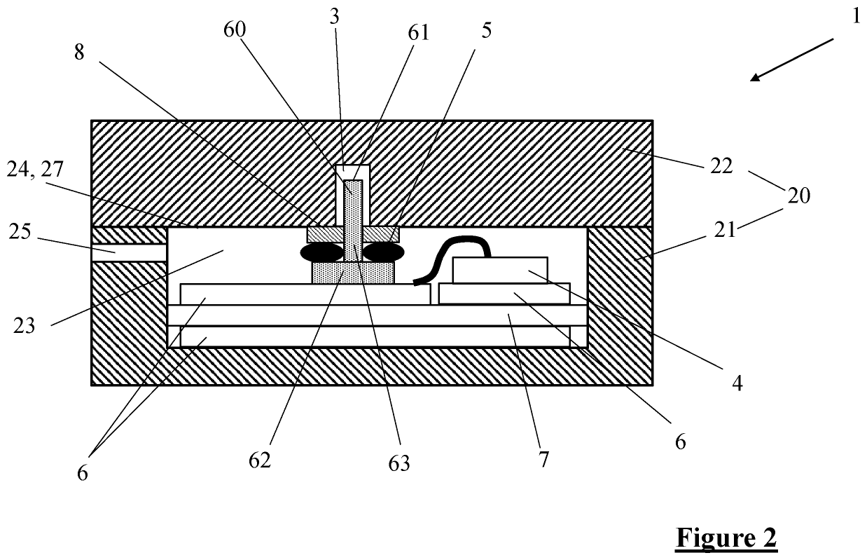

It can be seen further from FIG. 1 that in the open state of the encapsulation mold 20 the terminal end 61 of the contact pin 60 and at least part of the washer 8—received on the pin shaft 63 and supported by the sealing ring 5—protrudes in vertical direction over the parting plane 24, wherein the sealing ring 5 is in an undeformed state, in which the cross section of the sealing ring 5 shows a round, circular form. According to the invention the upper mold half 22 comprises a recess/opening 3 in the surface showing towards the cavity 23, which is configured to only receive the terminal end 61 of the contact pin 60 when the second, upper mold half 22 is placed in direct contact on the first, lower mold half 21, i.e. when the encapsulation mold 20 is closed and prepared for the encapsulation step (see also FIG. 2).

When the second, upper mold half 22—as shown by the arrow 26 in FIG. 1—is placed on the lower mold half 21, the washer 8 is pushed downwards along the pin shaft 63 axis, i.e. the pin shaft 63 longitudinal direction, into the cavity 23 of the mold 20, whereby, according to the invention, the sealing ring 5 resting stationary on the pin foot 62 is deformed elastically in axial direction and expands radially. In this state the sealing ring 5 shows a more or less oval cross section as can be seen in FIG. 2. FIG. 2 shows the final deformed state of the sealing ring 5 in the (fully) closed encapsulation mold 20. At this point, according to the invention, the cavity 23 of the mold 20 can be filled with encapsulation material 10 via the mold inlet 25 to encapsulate at least partially the substrate 7, the one or more semiconductors 4, and the perpendicular contact pin 60 together with the elastically deformed sealing ring 5 and the washer 8.

In the situation as shown with FIG. 2, the sealing ring 5 is forced to an elastically deformed state in the axial pin shaft 63 direction, whereby the elastic reaction forces of the sealing ring material provide sealing forces in axial direction of the sealing ring 5 upwards onto the washer 8 and downwards onto the pin foot 63. The washer 8 is pushed upwards by means of the elastic restoring forces of the deformed sealing ring 5, and is pressed against the lower mold surface, the cavity limiting surface 27 of the second upper mold half 22. This upwards directed elastic force causes a sealing effect of the washer 8 with the cavity limiting surface 27 in order to prevent that molding material 10 can flow during the molding step towards the pin shaft 63. Such an unwanted material flow would result in a contamination of the terminal end 61 of the contact pin 60. Due to the elastically restoring forces of the sealing ring 5 in axial direction, i.e. in pin shaft 63 direction, this access, and all other possible accesses for molding material 10 in radial direction to reach the pin shaft 63 and climb-up the pin shaft 63 are sealed actively by elastic restoring forces of the deformed sealing ring 5. By means of these elastic restoring forces sealed contacts of the washer 8 and the mold 20, of the washer 8 and the sealing ring 5, of the sealing ring 5 and the pin foot 62 at least in the axial/vertical directions are provided.

In the first exemplary embodiment as shown with FIGS. 1 to 3 the sealing ring 5 is deformed elastically such that the cross section of the sealing ring 5 is formed oval due to the compression in axial direction and is expanded in the radial directions (away and towards the pin shaft 63). This expansion effect towards the pin shaft 63 can be used to achieve a further sealing contact of the deformed sealing ring 5 with the pin shaft 63. However, as described above the axial oriented sealings are regularly sufficient to prevent that fluid molding material flows towards the pin shaft 63 and upwards along the pin shaft 63 to contaminate the terminal end 61 during the molding step.

FIG. 3 shows an encapsulated power module 1 according to the invention with a top contact, i.e. the terminal end 61 free of encapsulation material 10. The shown power module 1 can be contacted at a side basically parallel to the substrate 7. As a person skilled in the relevant art derives this can be in use of the power module any side and must not be the top side as shown with FIG. 3. A person skilled in the relevant art also will be aware that the shown embodiment for a power module will have at least one or more other contact terminals which, e.g. protrude in direction of the plane of the substrate 7, which would be in FIG. 3 in lateral direction. In this regard the embodiment shown with FIGS. 1 to 3 only show a simplified embodiment in order to illustrate the underlying idea of the invention.

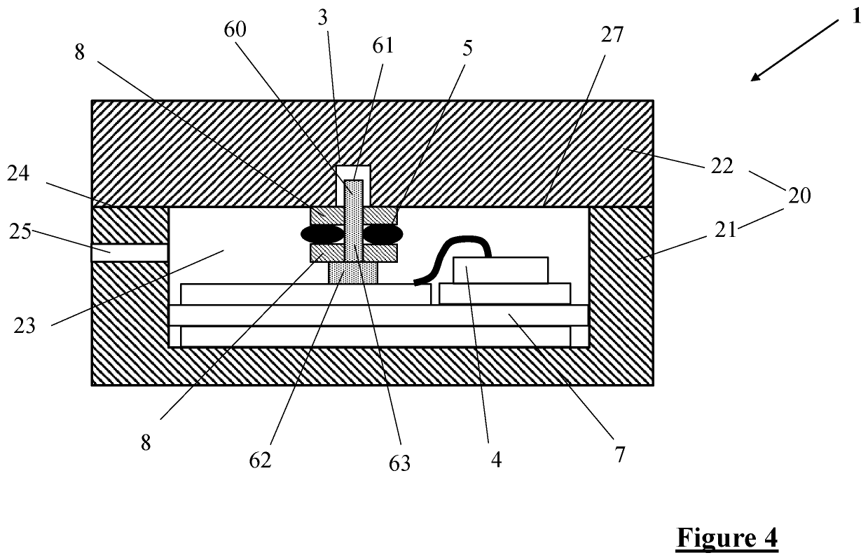

In FIG. 4 another implementation of idea according to the invention is shown. The embodiment of a power module 1 of FIG. 4 deviates from the embodiment shown with FIGS. 1 to 3 in that the sealing ring 5 is sandwiches between two washers 8. This possibility is preferred in particular when the pin foot 62 support surface for supporting the sealing ring 5 when being deformed by closing the mold 20 is not big enough to ensure a proper deformation of the sealing ring 5 and therewith sufficient high elastic restoring forces to provide sealed contacts in radial direction in order that no encapsulation material can enter between the mold inner surface 27, the washer 8, the sealing ring 5 and the pin foot 62. As can be seen from FIG. 2, the sealing ring 5 would slip over the pin foot 62 when pushed downwards if the second lower washer 8 would not be present. Hence, the height of the pin foot 62 would limit the elastic deformation of the sealing ring 5 and the restoring forces to ensure good sealing conditions between the mold inner surface 27, the washer 8, the sealing ring 5 and the pin foot 62. Therefore, a second, lower washer 8 is provided to rest on the pin foot 62 and provides support against the deformation of the sealing ring 5 when the mold is closed for performing the encapsulation step.

Hence, the solution shown with the embodiment of FIG. 4 is particularly preferred when the radial extension of the pin foots 62 is small or a press-fit pin is used, e.g. A person skilled in the relevant art will drive from FIG. 4 that washers covering or surrounding the pin foot, e.g. in from of a sleeve or the like, and proving a support surface for the sealing ring 5 are covered by the scope of the invention, even not shown in the Figures. It is further covered by the invention that the washers 8, independent from the illustrated embodiments, can comprise a circumferential sealing groove-like the known sealing grooves in the art—at least on that side which faces the sealing ring 5. The invention also covers the use of three or more washers, for instance for adapting the height of the washer/sealing ring-package to the height of the pin shaft. In this context it is also imaginable to use two sealing rings 5 and three washers 8 placed alternately one above the other such that each sealing ring 5 is sandwiched between two washers 8. Here a person skilled in the relevant art will find a lot of possibilities to come to a package filling the space between the pin foot 62 and the terminal end 61 of the contact pin 60 such that at least one sealing ring 5 is elastically deformed when the encapsulation mold 20 is closed. As these embodiments of the invention are within the range of the knowledge of a person skilled in the relevant art it is refrained from the illustration of these possibilities.

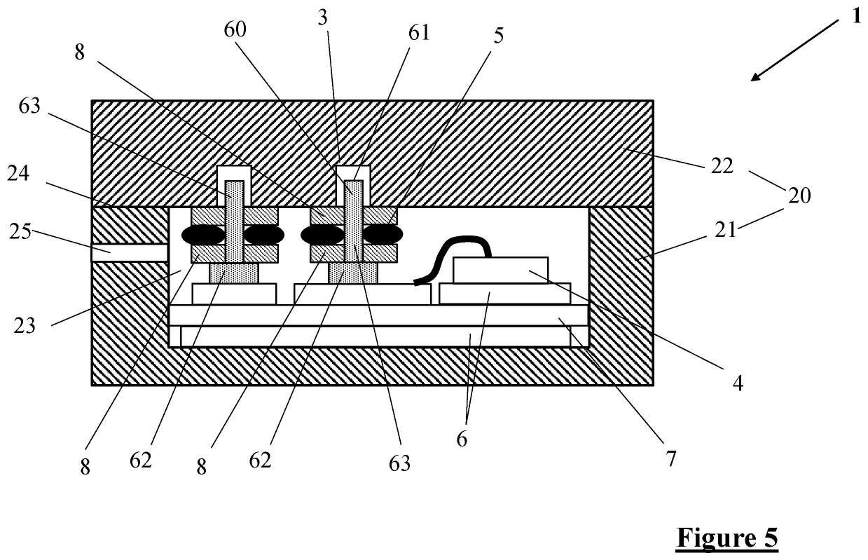

A further embodiment of the invention is shown with FIG. 5 from which it can be derived that the invention also covers power modules 1 having more than one contact pin 60 protruding basically perpendicular to the substrate 7. In the embodiment of FIG. 5 an embodiment with two contact pins 60 is shown as an embodiment representing all power modules 1 according to the invention with more than one contact pin protruding perpendicular to the substrate 7. A person skilled in the relevant art will detect that it is merely a question of design to arrange and fix two or even more perpendicular contact pins 60 on a substrate 7 or on the one or more semiconductors 4. In accordance with the number of perpendicular contact pins 60 the upper mold half must have the same number of recesses 3 at the corresponding locations such that the contact pins 60 are not damaged when closing the mold.

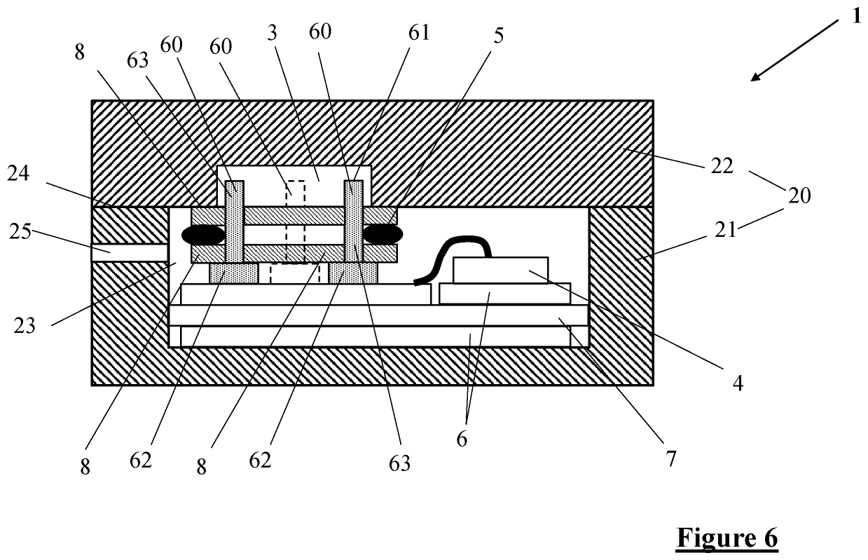

With FIG. 6 a further possibility for implementing the idea of the invention is illustrated, in which two washers 8 are configured as a kind of perforated plates having an equal number of holes to the number of contact pins 60 which should be guided free of molding material to the outside of the power module 1. In between the two washers 8 a sealing ring 5 is sandwiched, which is elastically deformed when the encapsulation mold 20 is closed. Here the sealing ring can be shaped like an O-Ring comprising a circular or oval form. Further, the upper washer 8 is not necessarily a perforated plate, since also can have, e.g., an elongated hole through which more than one contact pin shaft 63 can pass. According to the invention the entrance of molding material in an area between two contact pin shafts 63 has to be avoided. This is achieved as shown in the embodiment of FIG. 6 already by pressing the lower washer 8 onto the pin feet 62 by means of elastically deforming the sealing ring 5. As detectable by a person skilled in the relevant art without more, the sealing ring 5 can also be a kind of a disc elastically deformable for being able to transmit a sealing force in the longitudinal pin shaft direction. For a person skilled in the relevant art it is easily imaginable further that the two washers 8 together with the sealing ring 5 sandwiched therebetween could receive/surround more than two contact pins 60 respectively their pin shafts 63 as indicated in FIG. 6 by the contact pin 60 in depicted dotted lines.

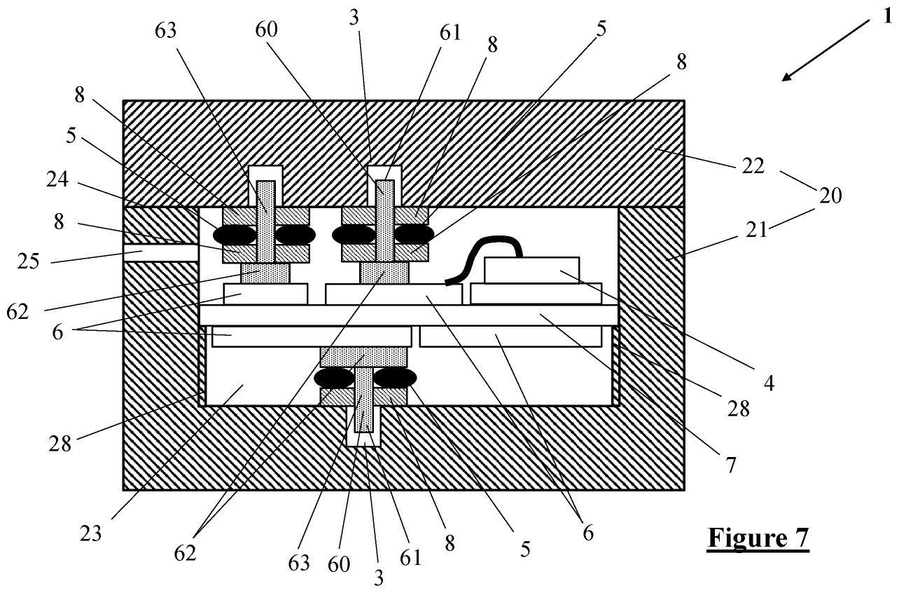

FIG. 7 shows a further embodiment for a power module according to the invention with contact pins 60 protruding perpendicular on either side of the substrate 7, i.e. on the upper side as well as on the lower side as depicted with FIG. 7. Here it has to be considered that the one or more contact pins 60 which are designed to project out of the cured encapsulation material with their terminal ends 61 require a corresponding recess 3 in the lower mold half 21. Further it has to be considered that the non-encapsulated power module 1 has to be pushed downward in order to compress elastically the sealing ring 5 received on the downward facing contact pin 60. For this a plurality of support ribs may be arranged in the lower mold half 21 of encapsulation mold 20 to limit the deformation of the sealing ring 5 and to prevent damaging the substrate 7 and the components thereon. The downwards movement of the substrate 7 with the attached components may be done similar to the before mentioned embodiments during placing the upper mold half 22 on the parting plane 24, therewith deforming all sealing rings 5 at the same time. Naturally this is only one of a plurality of possible solutions being in the range of the knowledge of a person skilled in the relevant art. The embodiment of FIG. 7 merely aims to show that the invention is not limited to provide power modules 1 and their method for manufacturing according to the invention having one or more terminal ends 61 projecting on only one side perpendicular to the substrate 7, since showing that the inventive arrangement of an elastically deformable sealing ring 5 and at least one washer 8 received on the respective pin shaft 63 is applicable also to embodiments of power modules having more than one terminal ends 61 protruding outside the power module housing 2, and independent whether the terminal ends 61 protrude outside the housing 2 on only one side or on two opposite sides, e. g. the top side and the bottom side.

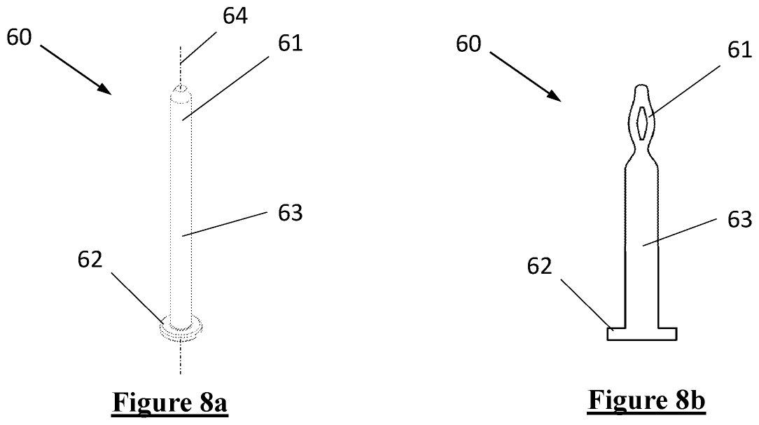

In FIG. 8 two contact pins 60 are illustrated as examples representing a plurality of contact pins which can be used in the implementation of the invention. FIG. 8a shows a contact pin 60 being rotationally symmetric with respect to the pin shaft axis 64 and showing a round cross section. The round pin foot 62 is preferably apt to be welded, e.g. by ultrasonic or laser, to the bonded or printed circuit 6 on a substrate 7. The contact pin 60 of FIG. 8b is an embodiment for a press-fit pin having, e.g. a rectangular cross section. These two possible contact pins 60 which can be used with the inventive idea show to a person skilled in the relevant art that any other kind of contact pin is usable with the invention to provide a simple way to lead/guide a terminal end 61 of contact pin 60 in a direction perpendicular to the substrate 7 outside of the power module 10, respectively through of the encapsulation housing 2 of the power module 1.

From the above disclosure and accompanying Figures and claims, it will be appreciated that the power module according to the invention and the method for manufacturing such a power module offers many possibilities and advantages over the prior art. It will be appreciated further by a person skilled in the relevant art that further modifications and changes known in the art could be made to a power module according to the invention without parting from the spirit of this invention. Therefore all these modifications and changes are within the scope of the claims and covered by them. It should be further understood that the examples and embodiments described above are for illustrative purposes only and that various modifications, changes, or combinations of embodiments in the light thereof, which will be suggested to a person skilled in the relevant art, are included in the spirit and purview of this application.

What is claimed is:

1. A semiconductor power module comprising:
one or more semiconductors placed on a substrate;
at least one contact pin extending basically perpendicular to the substrate and electrically connected to the substrate or the semiconductor via a pin foot, wherein a terminal end of the contact pin protrudes outside an encapsulation compound encapsulating at least partially the substrate, the one or more semiconductors, and the contact pin,
wherein
at least one sealing ring and at least one washer are received by a pin shaft of the contact pin such that they rest on the pin foot,
the washer is fixed by the encapsulation compound, and
the sealing ring is held in longitudinal direction of the pin shaft in an elastically deformed state by the washer.

2. The semiconductor power module according to claim 1, wherein the pin shaft shows a circular, oval, or rectangular cross section.

3. The semiconductor power module according to claim 1, wherein both the sealing ring and the washer show an annular, oval, or rectangular form, wherein the cross section of the sealing ring can be circular, oval, rectangular or of any other shape, and wherein the cross section of the washer is basically rectangular.

4. The semiconductor power module according to claim 1, wherein the sealing ring is sandwiched between the washer and the pin foot.

5. The semiconductor power module according to claim 1, wherein the sealing ring is sandwiched between two washers of which one contacts the pin foot.

6. The semiconductor power module according to claim 1, wherein the sealing ring is made of an elastomeric or silicone material, wherein the at least one washer or both washers are made of metal, plastic, reinforced plastic, or elastic material.

7. The semiconductor power module according to claim 1, wherein the pin foot is fixed to the substrate by means of ultrasonic welding, laser welding, soldering, bonding, sintering or press-fit.

8. The semiconductor power module according to claim 1, wherein two or more contact pins are fixed next to each other and perpendicular to the substrate, wherein one washer rests on the pin foot and one sealing ring is held elastically deformed in pin shaft direction by a second washer in a sandwiched manner, wherein each of the washers and the sealing ring surround all pin shafts.

9. The semiconductor power module according to claim 1, wherein one or more of the washers are made of electrically non-conducting material.

10. The semiconductor power module according to claim 1, wherein one or more contact terminals protrude laterally from the power module.

11. The semiconductor power module according to claim 1, wherein the contact pin is of the press-fit pin type of construction.

12. The semiconductor power module according to claim 1, wherein at least a second contact pin with at least one sealing ring and at least one washer received thereon is arranged in a analogous manner in the semiconductor power module, however protruding with its terminal end on the opposite side of the substrate from the encapsulation compound.

13. A method for manufacturing a semiconductor power module having one or more semiconductors placed on a substrate to which at least one contact pin extends perpendicularly, wherein a terminal end of the contact pin protrudes outside an encapsulation compound encapsulating at least partially the substrate, the one or more semiconductors, and the contact pin, the method comprising the steps of:
a) providing a substrate with one or more semiconductors placed on it,
b) fixing at least one contact pin extending perpendicularly to the substrate via a pin foot such that the substrate can be electrically connected via a terminal end of the contact pin,
c) placing a sealing ring and a washer over a pin shaft of the contact pin such that both the sealing ring and the washer rests on the pin foot and one of the sealing ring or the washer contacts the pin foot,
d) placing the substrate with the contact pin, the sealing ring, and the washer in a first mold half,
e) closing the first mold half in longitudinal direction of the pin shaft by means of a second mold half having a recess into which the terminal end can protrude, thereby elastically deforming the sealing ring by pressing the washer towards the pin foot by means of the second mold half,
f) filling the cavity of the mold with an encapsulating compound,
g) opening the mold after curing of the encapsulation compound, and
h) removing the semiconductor power module from the mold.
